(19) United States
(12) Patent Application Publication
(10) Pub. No.: US 2024/0215406 A1
(43) Pub. Date: Jun. 27, 2024

(54) DISPLAY APPARATUS

(71) Applicant: LG Display Co., Ltd., Seoul (KR)

(72) Inventors: Sejong SEONG, Paju-si (KR); SeHong PARK, Paju-si (KR); Wonrae KIM, Paju-si (KR); Inae CHOI, Paju-si (KR); SeoHyun NAM, Paju-si (KR)

(21) Appl. No.: 18/462,045

(22) Filed: Sep. 6, 2023

(30) Foreign Application Priority Data
Dec. 26, 2022 (KR) 10-2022-0184734

(51) Int. Cl. H10K 59/80; H10K 59/122; H10K 59/124

(52) U.S. Cl. CPC H10K 59/878; H10K 59/122; H10K 59/124

(57) ABSTRACT

A display apparatus is provided, which may improve light extraction efficiency of light emitted from a light emitting element layer. The display apparatus comprises a substrate having a plurality of pixels having a plurality of subpixels, a pattern portion disposed on the substrate and formed to be concave between the plurality of subpixels, and a reflective portion on the pattern portion, wherein the plurality of subpixels include a light emission area and a non-light emission area adjacent to the light emission area, and the pattern portion is disposed in the periphery of the non-light emission area.

### CROSS-REFERENCE TO RELATED APPLICATIONS

This application claims the benefit of the Korean Patent Application No. 10-2022-0184734 filed on Dec. 26, 2022, which is hereby incorporated by reference as if fully set forth herein.

### BACKGROUND

### Technical Field

The present disclosure relates to a display apparatus for displaying an image.

### Description of the Related Art

Since an organic light emitting display apparatus has a high response speed and low power consumption, does not require a separate light source unlike a liquid crystal display apparatus, and self-emits light to be individually driven for each pixel, the organic light emitting display apparatus may implement perfect black and thus the organic light emitting display apparatus has received attention as a next-generation flat panel display apparatus.

Such a display apparatus displays an image through light emission of a light emitting element layer that includes a light emitting layer interposed between two electrodes.

Meanwhile, light extraction efficiency of the display apparatus is reduced as some of light emitted from the light emitting element layer is not emitted to the outside due to total reflection on the interface between the light emitting element layer and an electrode and/or between a substrate and an air layer.

### BRIEF SUMMARY

The present disclosure has been made in view of the above problems and it is an object of the present disclosure to provide a display apparatus that may improve light extraction efficiency of light emitted from a light emitting element layer.

It is another object of the present disclosure to provide a display apparatus in which light extraction efficiency may be further improved through light extraction from a non-light emission area.

It is other object of the present disclosure to provide a display apparatus in which light may be extracted from a non-light emission area adjacent to a corner portion of a light emission area.

In addition to the objects of the present disclosure as mentioned above, additional objects and features of the present disclosure will be clearly understood by those skilled in the art from the following description of the present disclosure.

In accordance with an aspect of the present disclosure, the above and other objects can be accomplished by the provision of a display apparatus comprising a substrate having a plurality of pixels having a plurality of subpixels, a pattern portion disposed on the substrate and formed to be concave between the plurality of subpixels, and a reflective portion on the pattern portion, wherein the plurality of subpixels include a light emission area and a non-light emission area adjacent to the light emission area, and the pattern portion is disposed in the periphery of the non-light emission area.

In accordance with another aspect of the present disclosure, the above and other objects can be accomplished by the provision of a display apparatus comprising a substrate including a plurality of subpixel areas, and a light emitting element layer in the plurality of subpixel areas, wherein each of the plurality of subpixel areas includes a light emission area and a peripheral area in the periphery of the light emission area, and includes a reflective portion provided in the light emitting element layer in the peripheral area of each of the plurality of subpixel areas, and the light emitting element layer is formed to be concave on a pattern portion formed to be concave in the peripheral area.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a schematic plan view illustrating a display apparatus according to one embodiment of the present disclosure;

FIG. 2 is a schematic plan view illustrating one pixel shown in FIG. 1;

FIG. 3 is a schematic cross-sectional view taken along line I-I′ shown in FIG. 2;

FIG. 4 is a schematic cross-sectional view taken along line II-II′ shown in FIG. 2;

FIG. 5 is a schematic cross-sectional view taken along line III-III′ shown in FIG. 2;

FIG. 6 is an image illustrating light extraction characteristics of a non-light emission area of a display apparatus according to one embodiment of the present disclosure;

FIG. 7 is a modified example of FIG. 3, which illustrates a display apparatus according to the second embodiment of the present disclosure;

FIG. 8 is a modified example of FIG. 4, which illustrates a display apparatus according to the second embodiment of the present disclosure;

FIG. 9 is a modified example of FIG. 5, which illustrates a display apparatus according to the second embodiment of the present disclosure;

FIG. 10 is another modified example of FIG. 3, which illustrates a display apparatus according to the third embodiment of the present disclosure; and

FIG. 11 is another modified example of FIG. 5, which illustrates a display apparatus according to the fourth embodiment of the present disclosure.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts. Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details.

Like reference numerals refer to like elements throughout. In the following description, when the detailed description of the relevant known function or configuration is determined to unnecessarily obscure the important point of the present disclosure, the detailed description will be omitted.

In a case where ‘comprise,’ ‘have,’ and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when a position relation between two parts is described as ‘on˜,’ ‘over˜,’ ‘under˜,’ and ‘next˜,’ one or more other parts may be disposed between the two parts unless ‘just’ or ‘direct’ is used.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms.

These terms are only used to distinguish one element from another. For example, a first element could be termed a second element, and, similarly, a second element could be termed a first element, without departing from the scope of the present disclosure.

“X-axis direction,” “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure may be partially or overall coupled to or combined with each other and may be variously inter-operated with each other and driven technically as those skilled in the art can sufficiently understand.

The embodiments of the present disclosure may be carried out independently from each other or may be carried out together in co-dependent relationship.

Hereinafter, the preferred embodiments of the present disclosure will be described in detail with reference to the accompanying drawings.

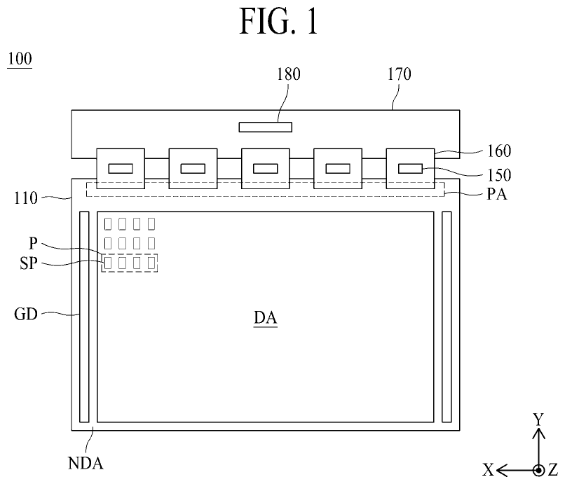

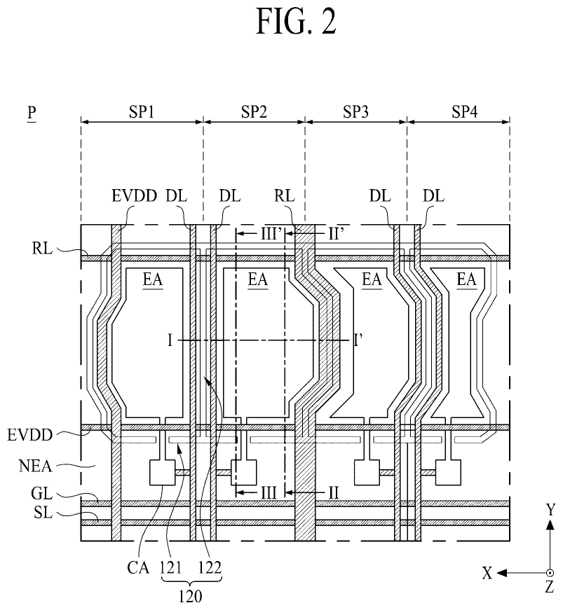

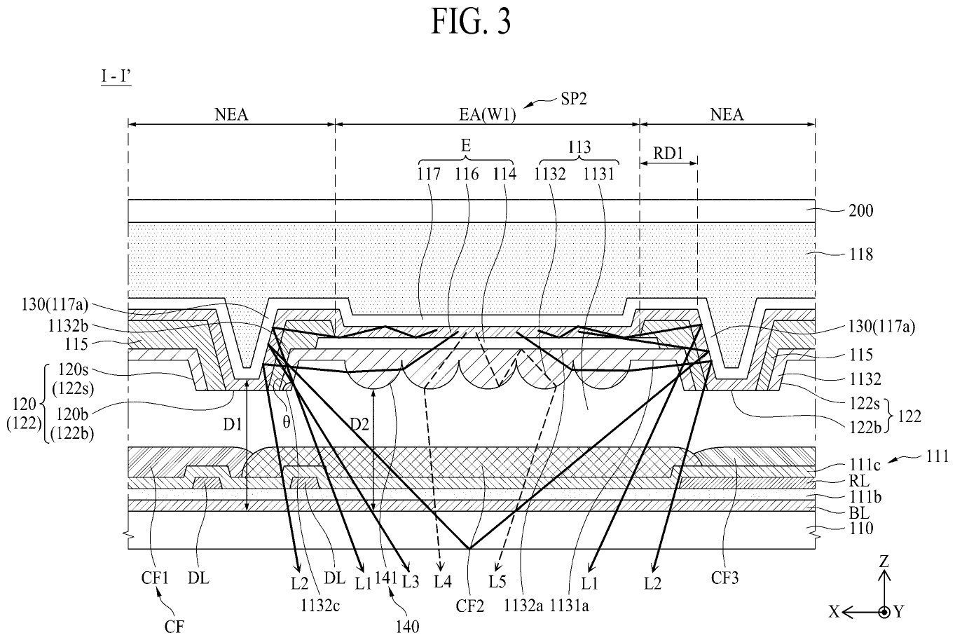

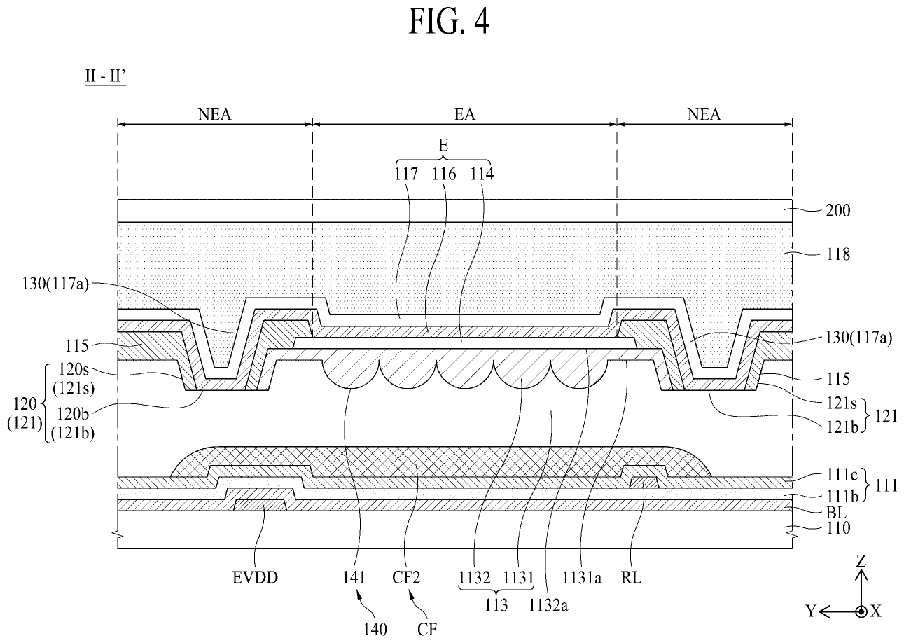

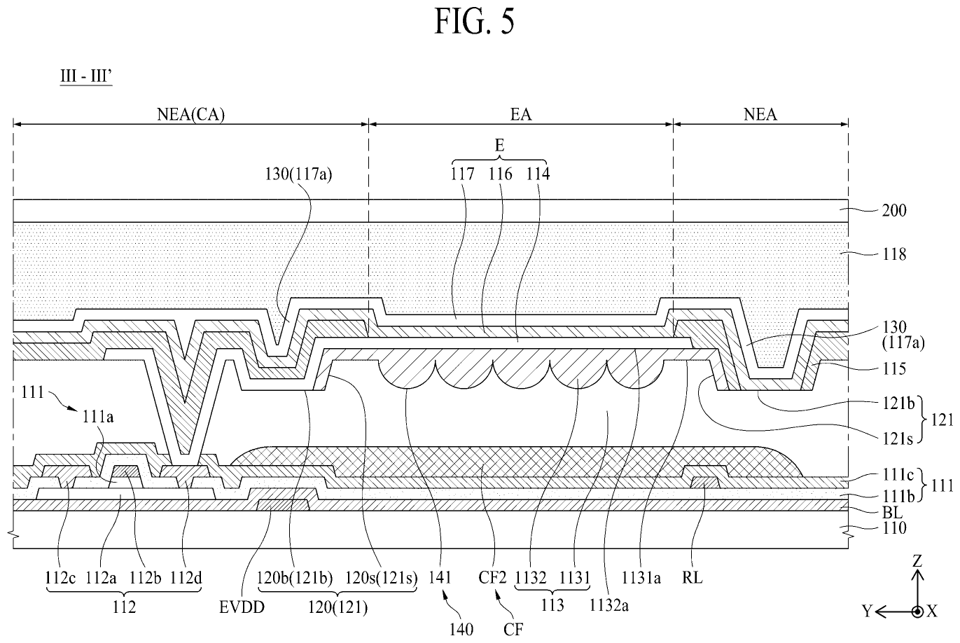

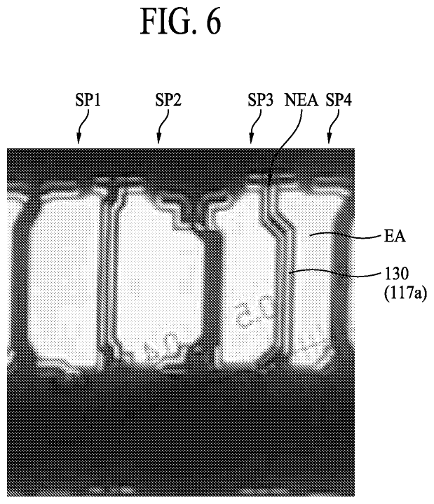

FIG. 1 is a schematic plan view illustrating a display apparatus according to one embodiment of the present disclosure, FIG. 2 is a schematic plan view illustrating one pixel shown in FIG. 1, FIG. 3 is a schematic cross-sectional view taken along line I-I′ shown in FIG. 2, FIG. 4 is a schematic cross-sectional view taken along line II-II′ shown in FIG. 2, FIG. 5 is a schematic cross-sectional view taken along line III-III′ shown in FIG. 2, and FIG. 6 is an image illustrating light extraction characteristics of a non-light emission area of a display apparatus according to one embodiment of the present disclosure.

Referring to FIGS. 1 to 6, a display apparatus 100 according to one embodiment of the present disclosure includes a substrate 110 having a plurality of pixels P having a plurality of subpixels SP, a pattern portion 120 disposed on the substrate 110 and formed to be concave between the plurality of subpixels SP, and a reflective portion 130 on the pattern portion 120. The plurality of subpixels SP may include a light emission area EA and a non-light emission area NEA adjacent to the light emission area EA. The pattern portion 120 may be disposed near or around the non-light emission area NEA(in other words, in a periphery of the non-light emission area NEA).

The light emission area EA is an area in which light is emitted, and may be expressed as the term of a display area. The non-light emission area NEA is an area in which light is not emitted, and may be expressed as the term of a non-display area or a peripheral area.

The display apparatus 100 according to one embodiment of the present disclosure may be provided with a reflective portion 130 near or around the non-light emission area NEA(in other words, in a periphery of the non-light emission area NEA), thereby reflecting light, which is directed toward an adjacent subpixel SP among light emitted from the light emission area EA, toward the light emission area EA of the subpixel SP for emitting light. Therefore, the display apparatus 100 according to one embodiment of the present disclosure may improve light extraction efficiency of the subpixel SP that emits light. The periphery of the non-light emission area NEA may refer to a partial area of the non-light emission area NEA spaced apart from or adjacent to the light emission area EA. For example, the periphery of the non-light emission area NEA may be an area spaced apart from the light emission area EA while surrounding the light emission area EA.

The pattern portion 120 according to one example may be formed to be concave near or around the non-light emission area NEA. For example, the pattern portion 120 may be formed to be concave in an overcoat layer 113 (shown in FIG. 3) on a substrate 110. As shown in FIG. 2, the pattern portion 120 may be provided to surround the light emission area EA. The pattern portion 120 may be disposed to be spaced apart from the light emission area EA. In FIG. 2, point hatching (or shading) is to indicate a bank. The pattern portion 120 according to one example may be provided to surround the light emission area EA in the form of a slit or a trench. For example, a width of the pattern portion 120 may be formed to be reduced from the reflective portion 130 toward the substrate 110. Also, as shown in FIG. 2, the pattern portion 120 may include an area exposed without being covered by a bank 115 (shown in FIG. 3). Therefore, the pattern portion 120 may be expressed as terms such as a groove, a slit, a trench, a bank slit and a bank trench.

The reflective portion 130 according to one example may be formed to be concave along a profile of the pattern portion 120 formed to be concave near or around the non-light emission area NEA, thereby being formed to be concave near or around the non-light emission area NEA. That is, the reflective portion 130 may be disposed along the peripheral area. The reflective portion 130 may be made of a material capable of reflecting light, and may reflect light, which is emitted from the light emission area EA and directed toward the adjacent subpixel SP, toward the light emission area EA for emitting light. Since the reflective portion 130 is disposed to be inclined while surrounding the light emission area EA on the pattern portion 120, the reflective portion 130 may be expressed as terms such as a side reflective portion and an inclined reflective portion.

Meanwhile, the display apparatus 100 according to one embodiment of the present disclosure may be implemented in a bottom emission type in which light emitted from the light emission area EA is emitted to a lower surface of the substrate 110. Therefore, in the display apparatus 100 according to one embodiment of the present disclosure, the light emitted to the lower surface of the substrate 110 may be the light in which direct light emitted from the light emission area EA and directly emitted to the lower surface of the substrate 110 and reflective light obtained by reflecting the light, which is emitted from the light emission area EA and directed toward the adjacent subpixel SP, by the reflective portion 130 and emitting the light to the lower surface of the substrate 100 are combined with each other. Therefore, the display apparatus 100 according to one embodiment of the present disclosure may more improve light extraction efficiency than the display apparatus in which the reflective portion 130 formed to be concave is not provided.

Hereinafter, reference to FIGS. 1 to 6, the display apparatus 100 according to an embodiment of the present specification will be described in more detail.

Referring to FIGS. 1 and 3, the display apparatus 100 according to one embodiment of the present disclosure may include a display panel having a gate driver GD, a light extraction portion 140 overlapping a light emission area EA, a source drive integrated circuit (hereinafter, referred to as “IC”) 150, a flexible film 160, a circuit board 170, and a timing controller 180.

The display panel may include a substrate 110 and an opposite substrate 200 (shown in FIG. 3).

The substrate 110 may include a thin film transistor, and may be a transistor array substrate, a lower substrate, a base substrate, or a first substrate. The substrate 110 may be a transparent glass substrate or a transparent plastic substrate. The substrate 110 may include a display area DA and a non-display area NDA.

The display area DA is an area where an image is displayed, and may be a pixel array area, an active area, a pixel array unit, a display unit, or a screen. For example, the display area DA may be disposed at a central portion of the display panel. The display area DA may include a plurality of pixels P.

The opposite substrate 200 may encapsulate (or seal) the display area DA disposed on the substrate 110. For example, the opposite substrate 200 may be bonded to the substrate 110 via an adhesive member (or clear glue). The opposite substrate 200 may be an upper substrate, a second substrate, or an encapsulation substrate.

The gate driver GD supplies gate signals to the gate lines in accordance with the gate control signal input from the timing controller 180. The gate driver GD may be formed on one side of the light emission area EA or in the non-light emission area NEA outside both sides of the light emission area EA in a gate driver in panel (GIP) method, as shown in FIG. 1.

The non-display area NDA is an area on which an image is not displayed, and may be a peripheral area, a signal supply area, an inactive area or a bezel area. The non-display area NDA may be configured to be in the vicinity of the display area DA. That is, the non-display area NDA may be disposed to surround the display area DA.

A pad area PA may be disposed in the non-display area NDA. The pad area PA may supply a power source and/or a signal for outputting an image to the pixel P provided in the display area DA. Referring to FIG. 1, the pad area PA may be provided above the display area DA.

The source drive IC 150 receives digital video data and a source control signal from the timing controller 180. The source drive IC 150 converts the digital video data into analog data voltages in accordance with the source control signal and supplies the analog data voltages to the data lines. When the source drive IC 150 is manufactured as a driving chip, the source drive IC 150 may be packaged in the flexible film 160 in a chip on film (COF) method or a chip on plastic (COP) method.

Pads, such as data pads, may be formed in the non-display area NDA of the display panel. Lines connecting the pads with the source drive IC 150 and lines connecting the pads with lines of the circuit board 170 may be formed in the flexible film 160. The flexible film 160 may be attached onto the pads by using an anisotropic conducting film, whereby the pads may be connected with the lines of the flexible film 160.

The circuit board 170 may be attached to the flexible films 160. A plurality of circuits implemented as driving chips may be packaged in the circuit board 170. For example, the timing controller 180 may be packaged in the circuit board 170. The circuit board 170 may be a printed circuit board or a flexible printed circuit board.

The timing controller 180 receives the digital video data and a timing signal from an external system board through a cable of the circuit board 170. The timing controller 180 generates a gate control signal for controlling an operation timing of the gate driver GD and a source control signal for controlling the source drive ICs 150 based on the timing signal. The timing controller 180 supplies the gate control signal to the gate driver GD, and supplies the source control signal to the source drive ICs 150.

Referring to FIGS. 2 and 3, the substrate 110 according to an example may include the light emission area EA and the non-light emission area NEA.

The light emission area EA is an area where an image is displayed, and may be a pixel array area, an active area, a display area, a pixel array unit, a display unit, or a screen. For example, the light emission area EA may be disposed at a central portion of the display panel.

The light emission area EA according to an example may include gate lines, data lines, pixel driving power lines, and a plurality of pixels P. Each of the plurality of pixels P may include a plurality of subpixels SP that may be defined by the gate lines and the data lines.

Meanwhile, at least four subpixels, which are provided to emit different colors and disposed to be adjacent to one another, among the plurality of subpixels SP may constitute one pixel P (or unit pixel). One pixel P may include, but is not limited to, a red subpixel, a green subpixel, a blue subpixel and a white subpixel. One pixel P may include three subpixels SP provided to emit light of different colors and disposed to be adjacent to one another. For example, one pixel P may include a red subpixel, a green subpixel and a blue subpixel.

Each of the plurality of subpixels SP includes a thin film transistor and a light emitting element layer E connected to the thin film transistor. Each of the plurality of subpixels may include a light emitting layer (or an organic light emitting layer) interposed between the pixel electrode and the reflective electrode.

The light emitting layer respectively disposed in the plurality of subpixels SP may individually emit light of their respective colors different from one another or commonly emit white light. According to an example, when the light emitting layer of the plurality of subpixels SP commonly emit white light, each of the red subpixel, the green subpixel and the blue subpixel may include a color filter CF (or wavelength conversion member CF) for converting white light into light of its respective different color. In this case, the white subpixel according to an example may not include a color filter.

In the display apparatus 100 according to one embodiment of the present disclosure, an area provided with a red color filter may be a red subpixel or a first subpixel, an area provided with a green color filter may be a green subpixel or a second subpixel, an area provided with a blue color filter may be a blue subpixel or a third subpixel, and an area in which the color filter is not provided may be a white subpixel or a fourth subpixel.

Each of the subpixels SP supplies a predetermined current to the organic light emitting element in accordance with a data voltage of the data line when a gate signal is input from the gate line by using the thin film transistor. For this reason, the light emitting layer of each of the subpixels may emit light with a predetermined brightness in accordance with the predetermined current.

The plurality of subpixels SP according to one example may be disposed to be adjacent to each other in a first direction (X-axis direction). The first direction (X-axis direction) may be a horizontal direction based on FIG. 2. The horizontal direction may be a direction in which a gate line GL is disposed.

A second direction (Y-axis direction) is a direction crossing the first direction (X-axis direction), and may be a vertical direction based on FIG. 2. The vertical direction may be a direction in which a data line DL is disposed.

A third direction (Z-axis direction) is a direction crossing each of the first direction (X-axis direction) and the second direction (Y-axis direction), and may be a thickness direction of the display apparatus 100.

The plurality of subpixels SP may include a first subpixel SP1, a second subpixel SP2, a third subpixel SP3 and a fourth subpixel SP4 arranged adjacent to each other in the first direction (X-axis direction). For example, the first subpixel SP1 may be a red subpixel, the second subpixel SP2 may be a green subpixel, the third subpixel SP3 may be a blue subpixel and the fourth subpixel SP4 may be a white subpixel, but is not limited thereto. However, the arrangement order of the first subpixel SP1, the second subpixel SP2, the third subpixel SP3 and the fourth subpixel SP4 may be changed.

Each of the first to fourth subpixels SP1 to SP4 may include a light emission area EA and a circuit area CA. The light emission area EA may be disposed at one side (or an upper side) of a subpixel area, and the circuit area CA may be disposed at the other side (or a lower side) of the subpixel area. For example, the circuit area CA may be disposed at the lower side of the light emission area EA based on the second direction Y. The light emission areas EA of the first to fourth subpixels SP1 to SP4 may have different sizes (or areas).

The first to fourth subpixels SP1 to SP4 may be disposed to be adjacent to one another along the first direction (X-axis direction). For example, two data lines DL extended along the second direction (Y-axis direction) may be disposed in parallel with each other between the first subpixel SP1 and the second subpixel SP2 and between the third subpixel SP3 and the fourth subpixel SP4. A pixel power line EVDD extended along the first direction (X-axis direction) may be disposed between the light emission area EA and the circuit area CA of each of the first to fourth subpixels SP1 to SP4. The gate line GL and a sensing line SL may be disposed below the circuit area CA. The pixel power line EVDD extended along the second direction (Y-axis direction) may be disposed at one side of the first subpixel SP1 or the fourth subpixel SP4. A reference line RL extended along the second direction (Y-axis direction) may be disposed between the second subpixel SP2 and the third subpixel SP3. The reference line RL may be used as a sensing line for sensing a change of characteristics of a driving thin film transistor and/or a change of characteristics of the light emitting element layer, which is disposed in the circuit area CA, from the outside in a sensing driving mode of the pixel P.

In the display apparatus 100 according to one embodiment of the present disclosure, each of the plurality of subpixels SP may include the light extraction portion 140. The light extraction portion 140 may be formed on the overcoat layer 113 (shown in FIG. 3) to overlap the light emission area EA of the subpixel. The light extraction portion 140 may be formed on the overcoat layer 113 of the light emission area EA to have a curved (or uneven) shape, thereby changing a propagation path of light emitted from the light emitting element layer E to increase light extraction efficiency. For example, the light extraction portion 140 may be a non-flat portion, an uneven pattern portion, a micro lens portion, or a light scattering pattern portion.

The light extraction portion 140 may include a plurality of concave portions 141. The plurality of concave portions 141 may be formed to be concave inside the overcoat layer 113. For example, the plurality of concave portions 141 may be formed or configured to be concave from an upper surface 1131a of a first layer 1131 included in the overcoat layer 113. Therefore, the first layer 1131 may include a plurality of concave portions 141. The first layer 1131 may be disposed between the substrate 110 and the light emitting element layer E.

A second layer 1132 of the overcoat layer 113 may be disposed between the first layer 1131 and the light emitting element layer E (or a pixel electrode 114 shown in FIG. 3). The second layer 1132 according to one embodiment may be formed to be wider than the pixel electrode 114 in the first direction (X-axis direction). Thus, the second layer 1132 may partially overlap the light emissive area EA, but is not limited thereto. As shown in FIG. 5, the second layer 1132 may be provided to be narrower than the pixel electrode 114 in the second direction (Y-axis direction), and may partially overlap the light emission area EA. Since the pixel electrode 114 is disposed on the upper surface 1132a of the second layer 1132, the upper surface 1132a of the second layer 1132 may be provided to be flat.

Meanwhile, a refractive index of the second layer 1132 may be greater than that of the first layer 1131. Therefore, as shown in FIG. 3, a path of light emitted from a light emitting layer 116 and directed toward the substrate 110 may be changed toward the reflective portion 130 due to a difference in refractive indexes between the second layer 1132 and the first layer 1131 of the overcoat layer 113. Therefore, the light having a path formed in the reflective portion 130 by the light extraction portion 140 may be reflected in the reflective portion 130 and emitted toward the light emission area EA of the subpixel SP for emitting light. Hereinafter, the light reflected in the reflective portion 130 and emitted toward the substrate 110 will be defined as the reflective light.

As shown in FIG. 3, the reflective light may include first reflective light L1 (or WG mode extraction light L1) reflected from the reflective portion 130 and emitted to the substrate 110 after being subjected to optical waveguide through total reflection between the pixel electrode 114 and the reflective electrode 117, second reflective light L2 reflected from the reflective portion 130 and emitted to the substrate 110 after its path is changed by the light extraction portion 140, and third reflective light L3 (or substrate mode extraction light L3) primarily reflected by the reflective portion 130 after being emitted from the light emitting layer 116, secondarily reflected on a boundary surface between the lower surface of the substrate 110 and the air layer and thirdly reflected by the reflective portion 130 and then emitted to the substrate 110. The first reflective light L1, the second reflective light L2 and the third reflective light L3, which are shown in solid lines in FIG. 3, may be the reflective light extracted by being reflected by the reflective portion 130.

As shown in FIG. 3, the first reflective light L1 according to one embodiment may be emitted from the light emission area EA. The second reflective light L2 may be emitted from a position spaced apart from the light emission area EA. That is, the second reflective light L2 may be emitted from the non-light emission area NEA or the peripheral area. Since a pixel driving line for pixel driving, for example, a data line DL is disposed between the first reflective light L1 and the second reflective light L2, a portion of the light reflected from the reflective portion 130 is covered by the data line DL and thus cannot be emitted toward the substrate 110. Therefore, as shown in FIG. 6, the second reflective light L2 may be emitted toward the substrate 110 from the position spaced apart from the light emission area EA, but is not limited thereto. The first reflective light L1 may be emitted toward the substrate 110 from the position spaced apart from the light emission area EA. The third reflective light L3 may be emitted from the light emission area EA or the non-light emission area NEA.

The display apparatus 100 according to one embodiment of the present disclosure may further include light which is emitted to the substrate 110 through the light extraction portion 140 without being reflected by the reflective portion 130. For example, as shown in FIG. 3, the display apparatus 100 may further include primary extraction light L4 emitted from the light emitting layer 116, refracted on a boundary surface between the plurality of concave portions 141 included in the light extraction portion 140 and the first layer 1131 and then emitted to the substrate 110, and recycle light L5 emitted from the light emitting layer 116, primarily refracted on the boundary surface between the plurality of concave portions 141 and the first layer 1131, secondarily reflected on the lower surface of the pixel electrode 114, refracted on the boundary surface between the plurality of concave portions 141 and the first layer 1131 and then emitted to the substrate 110. Therefore, the display apparatus 100 according to one embodiment of the present disclosure may improve the overall light extraction efficiency through the light extraction portion 140 and the reflective portion 130.

Meanwhile, in the display apparatus 100 according to one embodiment of the present disclosure, since the pattern portion 120 is disposed to surround the light emission area EA, at least a portion of the reflective portion 130 on the pattern portion 120 may be disposed to surround the light emission area EA. Therefore, the reflective light may be emitted toward the substrate 110 from the position spaced apart from the light emission area EA while surrounding at least a portion of the light emission area EA. As shown in the image of FIG. 6, it can be seen that the reflective light is emitted between the subpixels SP and from a corner portion of each subpixel SP. The corner portion may be an edge portion. In case of a general display apparatus, since the corner portion of the light emission area is bent at a predetermined angle, light emission efficiency may be reduced as compared with a central portion of the light emission area. In contrast, in the display apparatus 100 according to one embodiment of the present disclosure, since the reflective portion 130 is disposed in the non-light emission area surrounding the corner portion of the light emission area even though the corner portion of the light emission area is bent at a predetermined angle, light extraction may be performed, whereby the overall light emission efficiency may be increased.

Meanwhile, since FIG. 6 is exemplary, the reflective light may be emitted from the position spaced apart from the light emission area EA while surrounding the entire light emission area EA. Therefore, in the display apparatus 100 according to one embodiment of the present disclosure, since light dissipated by optical waveguide and/or light dissipated by the interface total reflection may be emitted from the non-light emission area NEA in the form of reflective light through the reflective portion 130 surrounding at least a portion of the light emission area EA, light extraction efficiency may be improved and the overall light emission efficiency may be increased.

Hereinafter, a structure of each of the plurality of subpixels SP will be described in detail.

Referring to FIG. 5, the display apparatus 100 according to one embodiment of the present disclosure may further include a buffer layer BL, a circuit element layer 111, a thin film transistor 112, a pixel electrode 114, a bank 115, a light emitting layer 116, a reflective electrode 117, an encapsulation layer 118 and a color filter CF.

In more detail, each of the subpixels SP according to one embodiment may include a circuit element layer 111 provided on an upper surface of a buffer layer BL, including a gate insulating layer 111a, an interlayer insulating layer 111b and a passivation layer 111c, an overcoat layer 113 provided on the circuit element layer 111, a pixel electrode 114 provided on the overcoat layer 113, a bank 115 covering an edge of the pixel electrode 114, a light emitting layer 116 on the pixel electrode 114 and the bank 115, a reflective electrode 117 on the light emitting layer 116, and an encapsulation layer 118 on the reflective electrode 117.

The thin film transistor 112 for driving the subpixel SP may be disposed on the circuit element layer 111. The circuit element layer 111 may be expressed as the term of an inorganic film layer. The buffer layer BL may be included in the circuit element layer 111 together with the gate insulating layer 111a, the interlayer insulating layer 111b and the passivation layer 111c. The pixel electrode 114, the light emitting layer 116 and the reflective electrode 117 may be included in the light emitting element layer E.

The buffer layer BL may be formed between the substrate 110 and the gate insulating layer 111a to protect the thin film transistor 112. The buffer layer BL may be disposed on the entire surface (or front surface) of the substrate 110. The pixel power line EVDD for pixel driving may be disposed between the buffer layer BL and the substrate 110. The pixel power line EVDD may be disposed below the bank 115 while being spaced apart from the thin film transistor 112. The buffer layer BL may serve to block diffusion of a material contained in the substrate 110 into a transistor layer during a high temperature process of a manufacturing process of the thin film transistor. Optionally, the buffer layer BL may be omitted in some cases.

The thin film transistor 112 (or a drive transistor) according to an example may include an active layer 112a, a gate electrode 112b, a source electrode 112c, and a drain electrode 112d.

The active layer 112a may include a channel area, a drain area and a source area, which are formed in a thin film transistor area of a circuit area of the subpixel SP. The drain area and the source area may be spaced apart from each other with the channel area interposed therebetween.

The active layer 112a may be formed of a semiconductor material based on any one of amorphous silicon, polycrystalline silicon, oxide and organic material.

The gate insulating layer 111a may be formed on the channel area of the active layer 112a. As an example, the gate insulating layer 111a may be formed in an island shape only on the channel area of the active layer 112a, or may be formed on an entire front surface of the substrate 110 or the buffer layer BL, which includes the active layer 112a.

The gate electrode 112b may be formed on the gate insulating layer 111a to overlap the channel area of the active layer 112a.

The interlayer insulating layer 111b may be formed on the gate electrode 112b and the drain area and the source area of the active layer 112a. As in FIG. 5, the interlayer insulating layer 111b may be formed in the circuit area and an entire light emission area, in which light is emitted to the subpixel SP. However, embodiments of the present disclosure are not limited thereto, the interlayer insulating layer 111b may be patterned between the drain electrode 112d and the gate electrode 112b and drain region of the active layer 112a and may be arranged in an island shape, and moreover, may be patterned between the source electrode 112c and the gate electrode 112b and source region of the active layer 112a and may be arranged in an island shape.

The source electrode 112c may be electrically connected to the source area of the active layer 112a through a source contact hole provided in the interlayer insulating layer 111b overlapped with the source area of the active layer 112a. The drain electrode 112d may be electrically connected to the drain area of the active layer 112a through a drain contact hole provided in the interlayer insulating layer 111b overlapped with the drain area of the active layer 112a.

The drain electrode 112d and the source electrode 112c may be made of the same metal material. For example, each of the drain electrode 112d and the source electrode 112c may be made of a single metal layer, a single layer of an alloy or a multi-layer of two or more layers, which is the same as or different from that of the gate electrode.

In addition, the circuit area may further include first and second switching thin film transistors disposed together with the thin film transistor 112, and a capacitor. Since each of the first and second switching thin film transistors is provided on the circuit area of the subpixel SP to have the same structure as that of the thin film transistor 112, its description will be omitted. The capacitor (not shown) may be provided in an overlap area between the gate electrode 112b and the source electrode 112c of the thin film transistor 112, which overlap each other with the interlayer insulating layer 111b interposed therebetween.

Additionally, in order to prevent a threshold voltage of the thin film transistor provided in a pixel area from being shifted by light, the display panel or the substrate 110 may further include a light shielding layer (not shown) provided below the active layer 112a of at least one of the thin film transistor 112, the first switching thin film transistor or the second switching thin film transistor. The light shielding layer may be disposed between the substrate 110 and the active layer 112a to shield light incident on the active layer 112a through the substrate 110, thereby minimizing a change in the threshold voltage of the transistor due to external light. Also, since the light shielding layer is provided between the substrate 110 and the active layer 112a, the thin film transistor may be prevented from being seen by a user.

The passivation layer 111c may be provided on the substrate 110 to cover the pixel area. The passivation layer 111c covers a drain electrode 112d, a source electrode 112c and a gate electrode 112b of the thin film transistor 112, and the buffer layer BL. The reference line RL may be disposed between the passivation layer 111c and the interlayer insulating layer 111b. The reference line RL may be disposed at a position symmetrical to the pixel power line EVDD based on the light emission area EA or a similar position symmetrical to the pixel power line EVDD. Therefore, as shown in FIG. 5, the reference line RL and the pixel power line EVDD may be disposed below the bank 115. The reference line RL may be provided on the same layer as the source and drain electrodes 112c and 112d. The passivation layer 111c may be formed over the circuit area and the light emission area. The passivation layer 111c may be omitted. The color filter CF may be disposed on the passivation layer 111c.

The overcoat layer 113 may be provided on the substrate 110 to cover the passivation layer 111c and the color filter CF. When the passivation layer 111c is omitted, the overcoat layer 113 may be provided on the substrate 110 to cover the circuit area. The overcoat layer 113 may be formed in the circuit area CA in which the thin film transistor 112 is disposed and the light emission area EA. In addition, the overcoat layer 113 may be formed in the other non-display area NDA except a pad area PA of the non-display area NDA and the entire display area DA. For example, the overcoat layer 113 may include an extension portion (or an enlarged portion) extended or enlarged from the display area DA to the other non-display area NDA except the pad area PA. Therefore, the overcoat layer 113 may have a size relatively wider than that of the display area DA.

The overcoat layer 113 according to one example may be formed to have a relatively thick thickness, thereby providing a flat surface on the display area DA and the non-display area NDA. For example, the overcoat layer 113 may be made of an organic material such as photo acryl, benzocyclobutene, polyimide and fluorine resin.

The overcoat layer 113 formed in the display area DA (or the light emission area EA) may include a plurality of concave portions 141. The plurality of concave portions 141 are the elements of the light extraction portion 140 for increasing light efficiency of the light emission area EA, and may be formed inside the overcoat layer 113. In detail, as shown in FIG. 5, the plurality of concave portions 141 may be formed in a concave shape on the first layer 1131 of the overcoat layer 113. The plurality of concave portions 141 are provided to be connected to each other so that an embossed shape may be formed in the first layer 1131.

The second layer 1132 having a refractive index higher than that of the first layer 1131 may be formed on the first layer 1131. A path of the light, which is directed toward the adjacent subpixel SP, among the light emitted from the light emitting element layer E may be changed toward the reflective portion 130 in accordance with a difference in the refractive index between the second layer 1132 and the first layer 1131. The second layer 1132 may be provided to cover the embossed shape of the first layer 1131 and thus the upper surface 1132a may be provided to be flat.

The pixel electrode 114 is formed on the upper surface 1132a of the second layer 1132 so that the pixel electrode 114 may be provided to be flat, and the light emitting layer 116 and the reflective electrode 117, which are formed on the pixel electrode 114, may be provided to be also flat. Since the pixel electrode 114, the light emitting layer 116, the reflective electrode 117, that is, the light emitting element layer E is provided to be flat in the light emission area EA, a thickness of each of the pixel electrode 114, the light emitting layer 116 and the reflective electrode 117 in the light emission area EA may be uniformly formed. Therefore, the light emitting layer 116 may be uniformly emitted without deviation in the light emission area EA.

The plurality of concave portions 141 may be formed on the first layer 1131 through a photo process using a mask having an opening portion and then a pattern (or etching) or ashing process after the first layer 1131 is coated to cover the passivation layer 111c and the color filter CF. The plurality of concave portions 141 may be formed in an area overlapped with the color filter CF and/or an area that is not overlapped with the bank 115 of the non-light emission area NEA, but are not limited thereto. A portion of the plurality of concave portions 141 may be formed to overlap the bank 115.

Referring back to FIG. 5, the color filter CF disposed in the light emission area EA may be provided between the substrate 110 and the overcoat layer 113. Therefore, the color filter CF may be disposed between the pixel power line EVDD, for example, the pixel power line EVDD and the reflective portion 130 or between the pixel driving line and the pattern portion 120. The color filter CF may include a red color filter (or a first color filter) CF1 for converting white light emitted from the light emitting layer 116 into red light, a green color filter (or a second color filter) CF2 for converting white light into green light, and a blue color filter (or a third color filter) CF3 for converting white light into blue light. The fourth subpixel, which is a white subpixel, may not include a color filter since the light emitting layer 116 emits white light.

As shown in FIG. 3, the display apparatus 100 according to one embodiment of the present disclosure may be provided such that color filters having different colors partially overlap each other at a boundary portion of the plurality of subpixels SP. In this case, the display apparatus 100 according to one embodiment of the present disclosure may prevent the light emitted from each subpixel SP from being emitted to the adjacent subpixel SP due to the color filters overlapped with each other at the boundary portion of the subpixels SP, thereby preventing color mixture between the subpixels SP from occurring.

The pixel electrode 114 of the subpixel SP may be formed on the overcoat layer 113. The pixel electrode 114 may be connected to a drain electrode or a source electrode of the thin film transistor 112 through a contact hole passing through the overcoat layer 113 and the passivation layer 111c. In FIG. 5, the pixel electrode 114 may be provided to be wider than the second layer 1132. However, the pixel electrode 114 may be provided to be narrower than the second layer 1132 in accordance with the cross-section position. For example, as shown in FIG. 3, the pixel electrode 114 may be provided to be narrower than the second layer 1132. As shown in FIG. 5, when the pixel electrode 114 is provided to be wider than the second layer 1132, an edge portion of the pixel electrode 114 may be connected to the drain electrode or the source electrode in the circuit area CA. In this case, the edge portion of the pixel electrode 114 may be covered by the bank 115. The pixel electrode 114 may be made of at least one of a transparent metal material or a semi-transmissive metal material.

Because the display apparatus 100 according to an embodiment of the present disclosure is configured as the bottom emission type, the pixel electrode 114 may be formed of a transparent conductive material (or TCO), such as indium tin oxide (ITO) or indium zinc oxide (IZO) capable of transmitting light, or a semi-transmissive conductive material such as magnesium (Mg), silver (Ag), or an alloy of Mg and Ag.

Meanwhile, the material constituting the pixel electrode 114 may include MoTi. The pixel electrode 114 may be a first electrode or an anode electrode.

The bank 115 is an area from which light is not emitted, and may be provided to surround each of the light emitting portions (or the concave portions 141) of each of the plurality of subpixels SP. That is, the bank 115 may partition (or define) the concave portions 141 of each of the light emitting portion or the subpixels SP. The light emitting portion may mean a portion where the pixel electrode 114 and the reflective electrode 117 are in contact with each of the upper surface and the lower surface of the light emitting layer 116 with the light emitting layer 116 interposed therebetween.

The bank 115 may be formed to cover the edge of each pixel electrode 114 of each of the subpixels SP and expose a portion of each of the pixel electrodes 114. That is, the bank 115 may partially cover the pixel electrode 114. Therefore, the bank 115 may prevent the pixel electrode 114 and the reflective electrode 117 from being in contact with each other at the end of each pixel electrode 114. The exposed portion of the pixel electrode 114, which is not covered by the bank 115, may be included in the light emitting portion. As shown in FIG. 5, the light emitting portion may be formed on the plurality of concave portions 141, and thus the light emitting portion (or the light emission area EA) may overlap the concave portions 141 in a thickness direction of the substrate 110.

After the bank 115 is formed, the light emitting layer 116 may be formed to cover the pixel electrode 114 and the bank 115. Therefore, the bank 115 may be provided between the pixel electrode 114 and the light emitting layer 116. The bank 115 may be expressed as the term of a pixel defining layer. The bank 115 according to one example may include an organic material. When the bank 115 is made of an organic material, the bank 115 in the non-light emission area NEA may have a different thickness depending on the position. In addition, when the bank 115 is made of an organic material, since the upper surface of the bank 115 may be provided to be flat, the light emitting layer 116, the reflective electrode 117 and the encapsulation layer 118, which are formed on the upper surface of the bank 115 in a subsequent process, may be provided to be also flat, but the present disclosure is not limited thereto. The bank 115 may be made of an inorganic material. When the bank 115 is made of an inorganic material, as shown in FIG. 3, the bank 115 may be formed to have the same or similar thickness along the profile of the pattern portion 120 (or the second layer 1132).

Referring again to FIG. 5, the light emitting layer 116 may be formed on the pixel electrode 114 and the bank 115. The light emitting layer 116 may be provided between the pixel electrode 114 and the reflective electrode 117. Thus, when a voltage is applied to each of the pixel electrode 114 and the reflective electrode 117, an electric field is formed between the pixel electrode 114 and the reflective electrode 117. Therefore, the light emitting layer 116 may emit light. The light emitting layer 116 may be formed of a plurality of subpixels SP and a common layer provided on the bank 115.

The light emitting layer 116 according to an embodiment may be provided to emit white light. The light emitting layer 116 may include a plurality of stacks which emit lights of different colors. For example, the light emitting layer 116 may include a first stack, a second stack, and a charge generating layer (CGL) provided between the first stack and the second stack. The light emitting layer may be provided to emit the white light, and thus, each of the plurality of subpixels SP may include a color filter CF suitable for a corresponding color.

The first stack may be provided on the pixel electrode 114 and may be implemented a structure where a hole injection layer (HIL), a hole transport layer (HTL), an emission layer (EML(B)), and an electron transport layer (ETL) are sequentially stacked.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant.

The second stack may be provided on the first stack and may be implemented in a structure where a hole transport layer (HTL), a yellow-green (YG) emission layer (EML(YG)), and an electron injection layer (EIL) are sequentially stacked.

In the display apparatus 100 according to an embodiment of the present disclosure, because the light emitting layer 116 is provided as a common layer, the first stack, the charge generating layer, and the second stack may be arranged all over the plurality of subpixels SP.

According to another embodiment, the light emitting layer 116 may be provided to emit lights of different colors and may be patterned in each of the plurality of subpixels SP. However, in this case, a hole injection layer (HIL), a hole transport layer (HTL), an emission transport layer (ETL), and an electron injection layer (EIL) except the light emitting layer may be arranged as a common layer in the subpixels SP. Also, in a case where the light emitting layer 116 is patterned in each of the subpixels SP, a color filter may not be provided between the substrate 110 and the light emitting layer 116.

The reflective electrode 117 may be formed on the light emitting layer 116. The reflective electrode 117 according to one example may include a metal material. The reflective electrode 117 may reflect the light emitted from the light emitting layer 116 in the plurality of subpixels SP toward the lower surface of the substrate 110. Therefore, the display apparatus 100 according to one embodiment of the present disclosure may be implemented as a bottom emission type display apparatus.

The display apparatus 100 according to one embodiment of the present disclosure is a bottom emission type and has to reflect light emitted from the light emitting layer 116 toward the substrate 110, and thus the reflective electrode 117 may be made of a metal material having high reflectance. The reflective electrode 117 according to one example may be formed of a metal material having high reflectance such as a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy may be an alloy such as silver (Ag), palladium (Pd) and copper (Cu). The reflective electrode 117 may be expressed as terms such as a second electrode, a cathode electrode and a counter electrode.

Meanwhile, in the display apparatus 100 according to one embodiment of the present disclosure, the reflective portion 130 may be a portion of the reflective electrode 117. Therefore, the reflective portion 130 may reflect light, which is directed toward the adjacent subpixel SP, toward the light emission area EA of the subpixel SP for emitting light. Since the reflective portion 130 is a portion of the reflection electrode 117, as shown in FIG. 3, the reflective portion 130 may be denoted by a reference numeral 117a. In the present disclosure, the reflective portion 130 may mean the reflective electrode 117 that overlaps the pattern portion 120. In particular, the reflective portion 130 may mean the reflective electrode 117 that is inclined while being overlapped with the pattern portion 120. Therefore, as shown in FIG. 3, the reflective portion 130 may reflect light that is directed toward the adjacent subpixel SP, or light that is dissipated through total reflection between interfaces, toward the light emission area EA of the subpixel SP for emitting light.

The encapsulation layer 118 is formed on the reflective electrode 117. The encapsulation layer 118 serves to prevent oxygen or moisture from being permeated into the light emitting layer 116 and the reflective electrode 117. To this end, the encapsulation layer 118 may include at least one inorganic film and at least one organic film.

Meanwhile, as shown in FIG. 3, the encapsulation layer 118 may be disposed not only in the light emission area EA but also in the non-light emission area NEA. The encapsulation layer 118 may be disposed between the reflective electrode 117 and an opposing substrate 200.

Hereinafter, the pattern portion 120 and the reflective portion 130 of the display apparatus 100 according to one embodiment of the present disclosure will be described in more detail with reference to FIGS. 1 to 6.

In the display apparatus 100 according to one embodiment of the present disclosure, the pattern portion 120 may be provided near the light emission area EA (or near the non-light emission area NEA) and the reflective portion 130 may be provided on the pattern portion 120 in order to prevent light extraction efficiency from being reduced as some of the light emitted from the light emitting element layer is not discharged to the outside due to total reflection on an interface between the light emitting element layer and the electrode and/or an interface between the substrate and the air layer.

For example, as shown in FIG. 3, the pattern portion 120 may be formed to be concave in the first layer 1131 of the overcoat layer 113. As shown in FIGS. 2 and 3, the pattern portion 120 may be disposed near or around the non-light emission area NEA. That is, the pattern portion 120 may be disposed to surround the light emission area EA while being adjacent to the light extraction portion 140. The pattern portion 120 may be formed in the non-light emission area NEA together with the plurality of concave portions 141 when the plurality of concave portions 141 are formed in the light emission area EA. The pattern portion 120 according to one embodiment may be disposed to surround the light emission area EA in the form of a slit or a trench. The pattern portion 120 may include a bottom surface 120b and an inclined surface 120s.

The bottom surface 120b of the pattern portion 120 according to one embodiment is a surface formed to be closest to the substrate 110, or may be disposed to be closer to the substrate 110 (or the upper surface of the substrate) than the pixel electrode 114 (or the lower surface of the pixel electrode 114) in the light emission area EA. Therefore, as shown in FIG. 3, the bottom surface 120b of the pattern portion 120 may be provided to have a depth equal to or similar to that of each of the plurality of concave portions 141. However, when the depth of the pattern portion 120 is lower than that of the concave portion 141, since an area of the reflective portion 130 is reduced, light extraction efficiency may be reduced. Therefore, in the display apparatus 100 according to one embodiment of the present disclosure, the depth of the pattern portion 120 may be provided to be equal to or deeper than that of the concave portion 141.

The inclined surface 120s of the pattern portion 120 may be disposed between the bottom surface 120b and the light extraction portion 140. Therefore, the inclined surface 120s of the pattern portion 120 may be provided to surround the light emission area EA or the plurality of concave portions 141. As shown in FIG. 3, the inclined surface 120s may be connected to the bottom surface 120b. The inclined surface 120s may form a predetermined angle θ with the bottom surface 120b. For example, the angle θ formed by the inclined surface 120s and the bottom surface 120b may be an obtuse angle. Therefore, a width of the pattern portion 120 may be gradually reduced toward a direction (or the third direction (Z-axis direction)) from the opposing substrate 200 (or the reflective portion 130) toward the substrate 110. As the obtuse angle is formed by the inclined surface 120s and the bottom surface 120b, the light emitting element layer E (or the light emitting element layer E including the reflective portion 130) including the second layer 1132, the bank 115 and the reflective portion 130, which are formed in a subsequent process, may be formed to be concave along the profile of the pattern portion 120. Therefore, the light emitting element layer E may be formed to be concave on the pattern portion 120 formed to be concave in the non-light emission area NEA (or the peripheral area). The light emitting element layer E formed to be concave in the pattern portion 120 may mean that it includes at least one of the pixel electrode 114, the light emitting layer 116 or the reflective electrode 117.

As shown in FIG. 2, the pattern portion 120 may be provided to surround the light emission area EA. As the pattern portion 120 is provided to surround the light emission area EA, at least a portion of the reflective portion 130 disposed on the pattern portion 120 may be provided to surround the light emission area EA. Therefore, in the display apparatus 100 according to one embodiment of the present disclosure, since light may be extracted even from the non-light emission area NEA near the light emission area EA, overall light efficiency may be improved. Therefore, the display apparatus 100 according to one embodiment of the present disclosure may have the same light emission efficiency or more improved light emission efficiency even with low power as compared with a general display apparatus having no pattern portion 120 and reflective portion 130, whereby overall power consumption may be reduced.

In addition, the display apparatus 100 according to one embodiment of the present disclosure may allow the light emitting element layer E to emit light even with low power, thereby improving lifespan of the light emitting element layer E.

Referring back to FIG. 2, the pattern portion 120 may include a first pattern line 121 disposed in the first direction (X-axis direction) between the circuit area CA and the light emission area EA and a second pattern line 122 disposed in the second direction (Y-axis direction) crossing the first direction (X-axis direction). Referring to FIG. 2, the first pattern line 121 may mean the pattern portion 120 disposed in a horizontal direction, and the second pattern line 122 may mean the pattern portion 120 disposed in a vertical direction.

The first pattern line 121 may include a bottom surface 121b and an inclined surface 121s. The second pattern line 122 may include a bottom surface 122b and an inclined surface 122s. Since each of the bottom surface 121b and the inclined surface 121s of the first pattern line 121 and each of the bottom surface 122b and the inclined surface 122s of the second pattern line 122 are the same as each of the bottom surface 120b and the inclined surface 120s of the pattern portion 120, their description will be replaced with the description of the bottom surface 120b and the inclined surface 120s of the pattern portion 120. The first pattern line 121 and the second pattern line 122 may be connected to one in the non-light emission area NEA (or the peripheral area) to surround the light emission area EA.

The first pattern line 121 may be disposed between the subpixels SP for emitting light of the same color. For example, the first pattern line 121 may be disposed between the first subpixels SP1 disposed in the second direction (Y-axis direction). Therefore, the first pattern line 121 may be disposed in the first direction (X-axis direction). In contrast, the second pattern line 122 may be disposed between the subpixels SP for emitting light of different colors. For example, the second pattern line 122 may be disposed between the first subpixel SP1 that is a red subpixel, and the second subpixel SP2 that is a green pixel. Therefore, the second pattern line 122 may be disposed in the second direction (Y-axis direction).

Since the second pattern line 122 is disposed between the subpixels SP for emitting light of different colors, the reflective portion 130 on the second pattern line 122 may prevent light of different colors from being emitted to other adjacent subpixels SP. Therefore, the display apparatus 100 according to the present disclosure may prevent color mixture (or color distortion) between the subpixels SP for emitting light of different colors, thereby improving color purity.

The second layer 1132 of the overcoat layer 113 may be further extended from the light emission area EA to the non-light emission area NEA to partially cover the inclined surface 120s of the pattern portion 120. Therefore, as shown in FIG. 3, an end 1132c of the second layer 1132 may be in contact with the bottom surface 120b of the pattern portion 120. In this case, the end 1132c of the second layer 1132 may be in contact with only a portion of the bottom surface 120b. When the second layer 1132 entirely covers the bottom surface 120b, the depth of the reflective portion 130 formed on the pattern portion 120 may be relatively lowered, thereby reducing reflective efficiency. Therefore, in the display apparatus 100 according to one embodiment of the present disclosure, the second layer 1132 is provided to be in contact with only a portion of the bottom surface 120b without entirely covering the bottom surface 120b of the pattern portion 120 and thus the reflective portion 130 formed in a subsequent process may be formed to be close to the bottom surface 120b, whereby reflective efficiency may be improved.

The bank 115 may be extended to cover the inclined surface 1132b of the second layer 1132 covering the inclined surface 120s of the pattern portion 120 while covering the edge of the pixel electrode 114. Therefore, the bank 115 may be in contact with a portion of the bottom surface 120b of the pattern portion 120, which is not covered by the second layer 1132. When the bank 115 entirely covers the bottom surface 120b, the depth of the reflective portion 130 formed on the pattern portion 120 is lowered, whereby reflective efficiency may be reduced. Therefore, as shown in FIG. 3, each of the second layer 1132 and the bank 115 on the bottom surface 120b of the pattern portion 120 may be discontinuously provided. That is, each of the second layer 1132 and the bank 115 may be disconnected on the bottom surface 120b of the pattern portion 120. As a result, in the display apparatus 100 according to one embodiment of the present disclosure, the bank 115 is provided to be in contact with only a portion of the bottom surface 120b without entirely covering the bottom surface 120b, so that the reflective portion 130 formed in a subsequent process may be formed to be close to the bottom surface 120b, whereby reflective efficiency may be improved.

Since the bank 115 is provided to be in contact with only a portion of the bottom surface 120b of the pattern portion 120, the bank 115 may be disconnected from the pattern portion 120 as shown in FIG. 3. Since FIG. 3 is a cross-sectional view of FIG. 2, the pattern portion 120 from which the bank 115 is disconnected may be the second pattern line 122. Therefore, the bank 115 may be disconnected from the second pattern line 122. As the bank 115 is disconnected from the second pattern line 122, the reflective portion 130 disposed on the second pattern line 122 may be disposed to be close to the bottom surface 122b of the second pattern line. Therefore, the reflective portion 130 may be formed as deep as possible in the second pattern line 122 as compared with the case that the bank is not disconnected from the second pattern line, and thus reflective efficiency may be improved. Since the second pattern line 122 is disposed between the subpixels SP for emitting light of different colors, prevention of color mixture or color distortion between the subpixels SP for emitting light of different colors may be maximized. As shown in FIG. 3, since the second pattern line 122 is disposed between the subpixels SP for emitting light of different colors, the second layer 1132, the bank 115, the light emitting layer 116 and the reflective portion 130 may be provided to be symmetrical based on the center of the pattern portion 120 (or the second pattern line 122).

The first pattern line 121 may be disposed between the subpixels SP for emitting light of the same color. Therefore, as shown in FIG. 4, the second layer 1132 may be formed only to a portion adjacent to the light emission area EA, and the second layer 1132 may not be formed on an opposite side of the light emission area EA based on the first pattern line 121. As a result, since the first pattern line 121 is disposed between the subpixels SP for emitting light of the same color, the bank 115, the light emitting layer 116 and the reflective portion 130 may be provided to be asymmetrical based on the center of the pattern portion 120 (or the first pattern line 121) as shown in FIG. 4.

Referring to FIG. 5, the first pattern line 121 may be disposed between the circuit area CA and the light emission area EA. As shown in FIG. 5, the pixel electrode 114 may be extended to the circuit area CA along a profile of the first pattern line 121 and a contact hole. Therefore, the edge of the pixel electrode 114 disposed in the circuit area CA may be in contact with the source electrode 112c or the drain electrode 112d of the thin film transistor 112.

The bank 115 may be disposed on the pixel electrode 114 disposed in the circuit area CA, and as shown in FIG. 5, may be formed along a profile of the pixel electrode 114. Therefore, the reflective portion 130 may be formed along a profile of the bank 115 even on the first pattern line 121 between the circuit area CA and the light emission area EA. Unlike the second pattern line 122, the bank 115 may not be disconnected from the first pattern line 121 between the circuit area CA and the light emission area EA. Therefore, the depth of the reflective portion 130 provided on the first pattern line 121 between the circuit area CA and the light emission area EA may be provided to be lower than the depth of the reflective portion 130 provided on the second pattern line 122.

FIG. 6 is an image illustrating light extraction characteristics of a non-light emission area of a display apparatus 100 according to one embodiment of the present disclosure, and shows a state that all of four subpixels SP emit light. Among the light emitted from the light emission area EA, the light that is directed toward an adjacent subpixel SP through total reflection between the interfaces or directed toward the adjacent subpixel SP due to its path change by the light extraction portion may be reflected in the reflective portion 130 formed to be concave on the pattern portion 120. Therefore, as shown in FIG. 6, the reflective light reflected by the reflective portion 130 may be emitted from the position spaced apart from the light emission area EA while surrounding the light emission area EA of each of the subpixels SP. Therefore, in the display apparatus 100 according to one embodiment of the present disclosure, since light dissipated by optical waveguide and/or light dissipated by the interface total reflection may be emitted from the non-light emission area NEA in the form of reflective light through the reflective portion 130 surrounding at least a portion of the light emission area EA, light extraction efficiency may be improved and the overall light emission efficiency may be increased.

Also, since light may be extracted even from the non-light emission area NEA due to the reflective portion 130 provided in the non-light emission area NEA, the display apparatus 100 according to one embodiment of the present disclosure may have the same light emission efficiency or more improved light emission efficiency even with low power as compared with a general display apparatus having no reflective portion, whereby overall power consumption may be reduced.

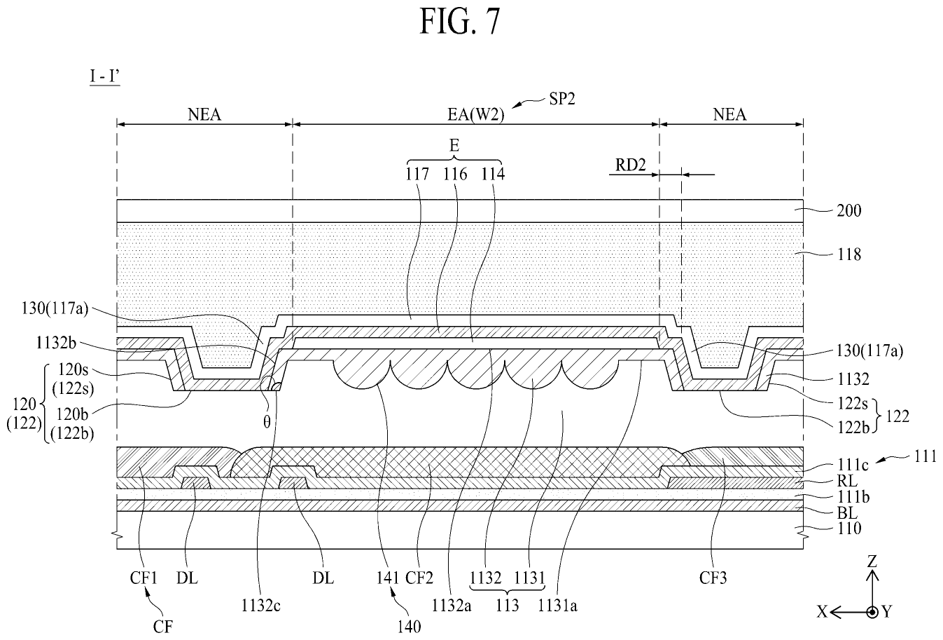

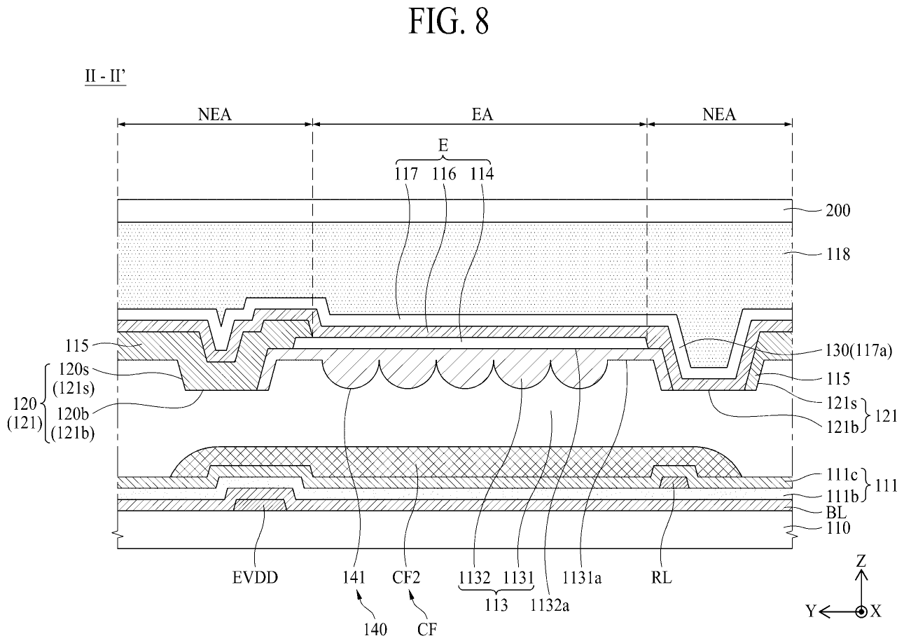

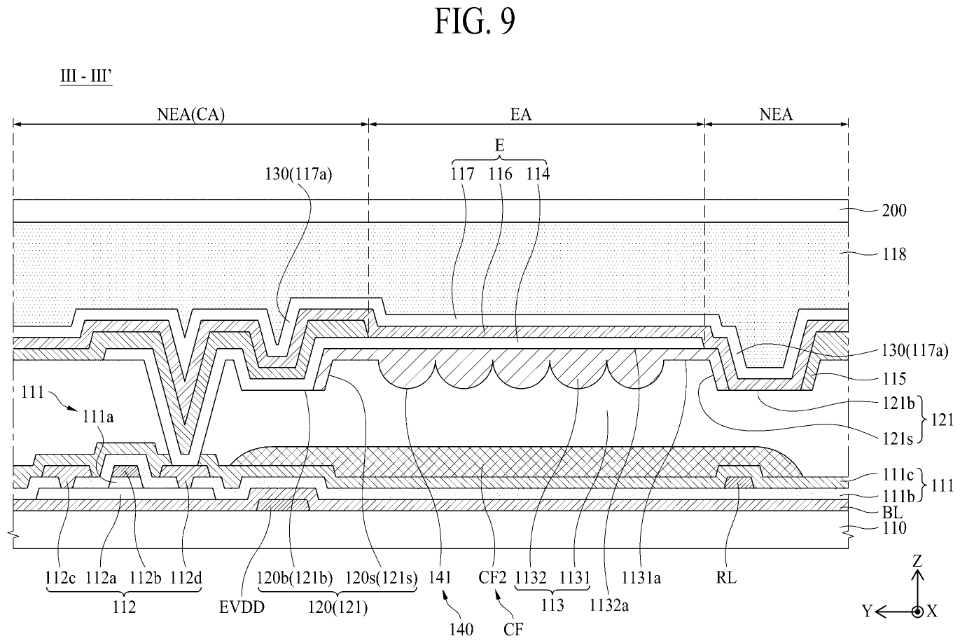

FIG. 7 is a modified example of FIG. 3, which illustrates a display apparatus according to the second embodiment of the present disclosure, FIG. 8 is a modified example of FIG. 4, which illustrates a display apparatus according to the second embodiment of the present disclosure, and FIG. 9 is a modified example of FIG. 5, which illustrates a display apparatus according to the second embodiment of the present disclosure.

Referring to FIGS. 7 to 9, the display apparatus 100 according to the second embodiment of the present disclosure is the same as the display apparatus according to FIGS. 3 to 5 except that a structure of the bank 115 is changed. Therefore, the same reference numerals will be given to the same elements as those of FIGS. 3 to 5, and the elements different from those of FIGS. 3 to 5 will be described below.

In case of the display apparatus according to FIG. 3 described above, the bank 115 is provided to cover the edge of the pixel electrode 114 while surrounding the entire light emission area EA. Therefore, in case of the display apparatus according to FIG. 3, a short between the pixel electrode 114 and the reflective electrode 117 may be prevented from occurring, and a portion of the light emitted from the light emission area EA may be reflected by the reflective portion 130 and emitted to the non-light emission area NEA and/or the light emission area EA. Meanwhile, in case of the display apparatus according to FIG. 3, since the bank 115 surrounds the entire light emission area EA, a width W1 of the light emission area EA in the first direction (X-axis direction) may be defined by the bank 115.

In contrast, in case of the display apparatus according to FIG. 7, the bank 115 may be disposed only in the first pattern line 121. Therefore, as shown in FIG. 7, since the bank 115 is not disposed in the second pattern line 122, the light emission area EA may be defined by the pixel electrode 114. Therefore, in case of the display apparatus according to FIG. 7, a width W2 of the light emission area EA in the first direction (X-axis direction) may be defined by a length of the pixel electrode 114. In case of the display apparatus according to FIG. 7, since the bank 115 is not disposed in the second pattern line 122, the width W2 of the light emission area EA in the first direction (X-axis direction) may be provided to be wider than the width W1 of the light emission area EA of the display apparatus according to FIG. 3 in the first direction (X-axis direction). Therefore, in the display apparatus 100 according to the second embodiment of the present disclosure, since a size of the light emission area EA may be increased, light emission efficiency may be further improved. The first pattern line 121 on which the bank 115 is disposed may mean the first pattern line 121 disposed between the circuit area CA and the light emission area EA, which are disposed in one subpixel SP. In this case, the circuit area CA may mean an area that includes the periphery of the circuit area CA.

Meanwhile, in case of the display apparatus according to FIG. 7, since the bank 115 is not disposed in the second pattern line 122, a distance (or reflective distance) RD2 between the end of the light emission area EA and the reflective portion 130 may be shorter than the case that the bank is provided. Therefore, the reflective distance RD2 of the display apparatus according to FIG. 7 may be shorter than a reflective distance RD1 of the display apparatus according to FIG. 3. Therefore, since the display apparatus 100 according to FIG. 7 may reflect light toward the substrate 110 by the reflective portion 130 before the light is dissipated through total reflection between the interfaces, light extraction efficiency may be further improved.

In addition, the display apparatus according to FIG. 7 has a structural feature in which the light emitting layer 116 is directly in contact with the inclined surface 1132b of the second layer 1132 covering the inclined surface 120s of the pattern portion 120 and is partially and directly in contact with the bottom surface 120b of the pattern portion 120 because the bank 115 is not disposed in the second pattern line 122.

In case of the display apparatus according to the second embodiment of the present disclosure, the bank 115 may be disposed only in the first pattern line 121 between the circuit area CA and the light emission area EA in one subpixel SP. Therefore, as shown in FIGS. 8 and 9, the bank 115 may be disposed on only one of the inclined surfaces 121s of the first pattern line 121 in the first pattern line 121 disposed between the circuit areas of the other subpixels SP. Therefore, the width of the light emission area EA in the second direction (Y-axis direction) in the display apparatus according to FIG. 8 may be wider than that of the light emission area EA in the second direction (Y-axis direction) in the display apparatus according to FIG. 4. For the same reason, the width of the light emission area EA in the second direction (Y-axis direction) in the display apparatus according to FIG. 9 may be wider than that of the light emission area EA in the second direction (Y-axis direction) in the display apparatus according to FIG. 5.

As a result, in the display apparatus 100 according to the second embodiment of the present disclosure, the bank 115 is provided so as not to be disposed in the second pattern line 122, so that the entire size of the light emission area EA may be more increased than the case that the bank is provided in the second pattern line, whereby light efficiency may be further improved.

Also, in the display apparatus 100 according to the second embodiment of the present disclosure, the bank 115 is provided so as not to be disposed on a portion of the pattern portion 120, so that the distance (that is, the reflective distance) between the end portion of the light emission area EA and the reflective portion 130 may be reduced, whereby light extraction efficiency may be maximized.

Meanwhile, in the display apparatus 100 according to the second embodiment of the present disclosure, since the bank 115 is only disposed in the circuit area CA and the first pattern line 121 in the periphery of the circuit area CA, the bank 115 may be provided as a black bank. Therefore, the display apparatus 100 according to the second embodiment of the present disclosure may further improve black visibility as compared with the case that an image is not output.

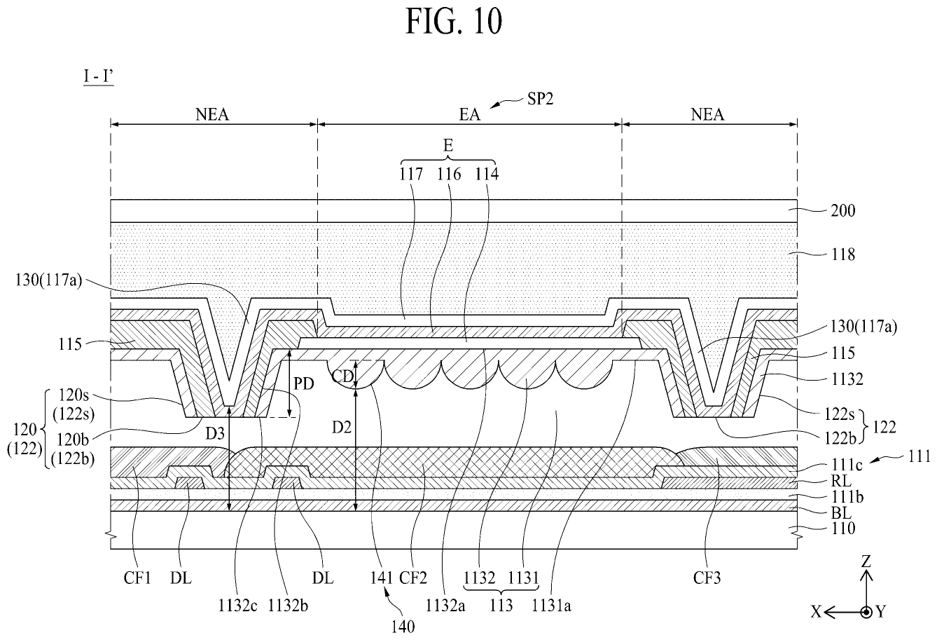

FIG. 10 is another modified example of FIG. 3, which illustrates a display apparatus according to the third embodiment of the present disclosure.

The display apparatus 100 according to the third embodiment of the present disclosure is the same as the display apparatus according to FIGS. 3 to 5 except that the structure of the pattern portion 120 is changed. Therefore, the same reference numerals will be given to the same elements as those of FIGS. 3 to 5, and the elements different from those of FIGS. 3 to 5 will be described below.

In case of the display apparatus according to FIG. 3 described above, the depth of the pattern portion 120 is provided to be the same as or similar to that of each of the plurality of concave portions 141. In this case, the depth of the pattern portion 120 may mean the distance from the lower surface of the pixel electrode 114 to the bottom surface 120b of the pattern portion 120. The depth of the concave portion 141 may mean the maximum depth of the concave portion 141 formed in the first layer 1131. Therefore, a distance D1 where the reflective portion 130 disposed on the pattern portion 120 is spaced apart from the upper surface of the substrate 110 may be longer than a distance D2 where the concave portion 141 is spaced apart from the upper surface of the substrate 110.

In contrast, in case of the display apparatus according to FIG. 10, a depth PD of the pattern portion 120 may be greater than a depth CD of each of the plurality of concave portions 141. Therefore, a distance D3 where the reflective portion 130 disposed on the pattern portion 120 is spaced apart from the upper surface of the substrate 110 may be shorter than the distance D2 where the concave portion 141 is spaced apart from the upper surface of the substrate 110. A pattern process time of the first layer 1131 in a position where the pattern portion is formed may be more increased than that of the first layer 1131 in a position where the plurality of concave portions 141 are formed, so that the depth of the pattern portion 120 may be greater. Therefore, in the display apparatus according to FIG. 10, since the reflective portion 130 may be disposed to be closer to the substrate 110, the size of the reflective portion 130 disposed in the pattern portion 120 may be increased. Therefore, in the display apparatus according to FIG. 10, since reflective efficiency of the reflective portion 130 may be increased, light extraction efficiency may be maximized.

Meanwhile, when the pattern portion is formed to be too deep, the reflective portion may be positioned to be close to the pixel driving line, for example, the data line, whereby parasitic capacitance may be generated. However, in the display apparatus 100 according to the third embodiment of the present disclosure, the color filter CF is disposed between the pattern portion 120 (or the second pattern line 122) and the pixel driving line (or the passivation layer 111c), so that the depth of the pattern portion 120 may be limited, whereby parasitic capacitance may not be generated between the reflective portion 130 and the pixel driving line.

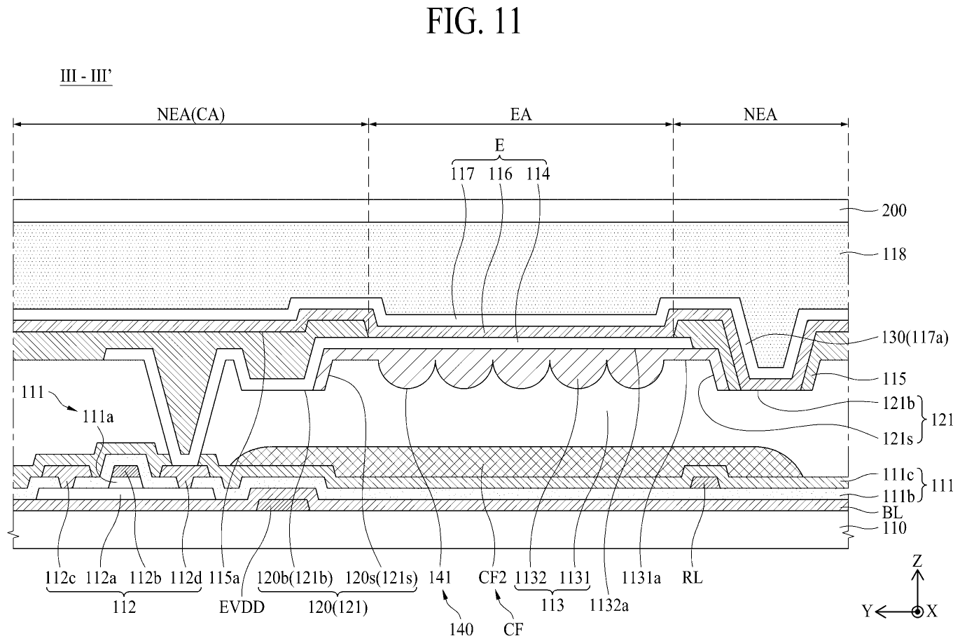

FIG. 11 is another modified example of FIG. 5, which illustrates a display apparatus according to the fourth embodiment of the present disclosure.

The display apparatus 100 according to the fourth embodiment of the present disclosure is the same as the display apparatus of FIG. 5 except that the structure of the bank 115 is changed. Therefore, the same reference numerals will be given to the same elements as those of FIG. 5, and the elements different from those of FIG. 5 will be described below.

In case of the display apparatus according to FIG. 5 described above, the bank 115 disposed on the pattern portion 120 (or the first pattern line 121) between the circuit area CA (or the non-light emission area NEA including the circuit area CA) and the light emission area EA is formed along the profile of the pattern portion 120. Therefore, in case of the display apparatus according to FIG. 5, the reflective portion 130 may be formed to be concave along the profile of the bank 115 even in the pattern portion 120 (or the first pattern line 121) between the circuit area CA (or in the non-light emission area NEA including the circuit area CA) and the light emission area EA. Therefore, the display apparatus according to FIG. 5 may emit the reflective light by the reflective portion 130 even from the non-light emission area NEA between the circuit area CA and the light emission area EA.

On the other hand, in case of the display apparatus according to FIG. 11, the upper surface 115a of the bank 115 disposed on the pattern portion 120 (or the first pattern line 121) between the circuit area CA (or the non-light emission area NEA including the circuit area CA) and the light emission area EA may be provided to be flat without following the profile of the pattern portion 120 (or the first pattern line 121). Therefore, in case of the display apparatus according to FIG. 11, the thickness of the bank 115 disposed on the pattern portion 120 (or the first pattern line 121) between the circuit area CA (or the non-light emission area NEA including the circuit area CA) and the light emission area EA is thickly provided (in other words, is relatively thicker), so that the distance between the pixel electrode 114 and the reflective electrode 117 may be increased. Therefore, in the display apparatus according to FIG. 11, since the formation of an electric field between the pixel electrode 114 and the reflective electrode 117 in the non-light emission area NEA in the periphery of the circuit area CA may be avoided, light emission of the light emission layer 116 from the non-light emission area NEA may be avoided.

As a result of, the display apparatus 100 according to the present disclosure may obtain the following effects.

First, in the display apparatus 100 according to the present disclosure, the reflective portion 130 is provided on the pattern portion 120 in the periphery of the non-light emission area NEA between the plurality of subpixels SP so that the reflective light may be extracted even from the non-light emission area NEA, whereby overall light efficiency may be improved.

Second, in the display apparatus 100 according to the present disclosure, light may be extracted even from the non-light emission area NEA due to the reflective portion 130 provided on the pattern portion 120 of the non-light emission area NEA, so that the display apparatus 100 according to the present disclosure may have the same light emission efficiency or more improved light emission efficiency even with low power as compared with the display apparatus having no reflective portion, whereby overall power consumption may be reduced.

Third, the display apparatus 100 according to one embodiment of the present disclosure may allow the light emitting element layer E to emit light even with low power, thereby improving lifespan of the light emitting element layer E.

Fourth, in the display apparatus 100 according to the present disclosure, as each of the plurality of subpixels SP includes the light extraction portion 140 that includes the plurality of concave portions 141, a path of the light, which is directed toward the adjacent subpixel SP, among the light emitted from the light emitting element layer may be changed so that the light may be extracted through the reflective portion 130, whereby light extraction efficiency may be maximized.

Fifth, in the display apparatus 100 according to one embodiment of the present disclosure, the light emitted from each subpixel SP may be prevented from being emitted to the adjacent subpixel SP due to the color filters overlapped with each other at the boundary portion of the subpixels SP, whereby color mixture between the subpixels SP may be prevented from occurring.

Sixth, in the display apparatus 100 according to one embodiment of the present disclosure, since the reflective portion 130 is disposed on the pattern portion 120 between the subpixels SP for emitting light of different colors, light of different colors may be more effectively prevented from being emitted to other adjacent subpixels SP. Therefore, the display apparatus 100 according to the present disclosure may prevent color mixture (or color distortion) between the subpixels SP for emitting light of different colors, thereby improving color purity.

According to the present disclosure, the following advantageous effects may be obtained.

In the display apparatus according to the present disclosure, the reflective portion is provided on the pattern portion in the periphery of the non-light emission area between the plurality of subpixels, so that the light may be extracted even from the non-light emission area, whereby overall light efficiency may be improved.

In the display apparatus according to the present disclosure, since the light may be extracted even from the non-light emission area, the display apparatus according to the present disclosure may have the same light emission efficiency or more improved light emission efficiency even with low power as compared with the display apparatus having no reflective portion, whereby overall power consumption may be reduced.

In the display apparatus according to the present disclosure, since the reflective portion is disposed in the non-light emission area adjacent to the corner portion of the light emission area, the light may be extracted even from the non-light emission area adjacent to the corner portion of the light emission area, whereby light emission efficiency may be increased.

In the display apparatus according to the present disclosure, each of the plurality of subpixels includes the light extraction portion that includes the plurality of concave portions, so that light extraction efficiency of the light emitted from the light emitting element layer may be maximized.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate having a plurality of pixels having a plurality of subpixels;
a pattern portion disposed on the substrate and is concave between the plurality of subpixels; and
a reflective portion on the pattern portion,
wherein the plurality of subpixels include a light emission area and a non-light emission area adjacent to the light emission area, and
the pattern portion is disposed in a periphery of the non-light emission area.

2. The display apparatus of claim 1, wherein the pattern portion surrounds the light emission area in the form of a slit or a trench.

3. The display apparatus of claim 1, wherein the plurality of subpixels include an overcoat layer on the substrate and a pixel electrode on the overcoat layer, and
the pattern portion is concave in the overcoat layer, the pattern portion includes a bottom surface, and the bottom surface of the pattern portion is disposed to be closer to the substrate than the pixel electrode in the light emission area.

4. The display apparatus of claim 1, wherein a width of the pattern portion is reduced from the reflective portion toward the substrate.

5. The display apparatus of claim 3, wherein the pattern portion includes an inclined surface connected to the bottom surface, and the inclined surface of the pattern portion is an obtuse angle with the bottom surface.

6. The display apparatus of claim 5, further comprising a bank covering an edge of the pixel electrode,
wherein the overcoat layer includes a second layer covering the inclined surface of the pattern portion, and
the bank covers the second layer covering the inclined surface and is in contact with a portion of the bottom surface of the pattern portion, wherein each of the second layer and the bank on the bottom surface of the pattern portion is discontinuous.

7. The display apparatus of claim 3, wherein the plurality of subpixels include a circuit area in the non-light emission area, and
the pattern portion includes a first pattern line disposed in a first direction between the circuit area and the light emission area and a second pattern line disposed in a second direction crossing the first direction.

8. The display apparatus of claim 7, further comprising a bank covering an edge of the pixel electrode, and
the bank is disconnected from the second pattern line.

9. The display apparatus of claim 1, wherein the plurality of subpixels include a light extraction portion overlapped with the light emission area, and
the pattern portion is disposed to be adjacent to the light extraction portion wherein the plurality of subpixels include an overcoat layer on the substrate and a pixel electrode on the overcoat layer, and
the light extraction portion is disposed on the overcoat layer and includes a plurality of concave portions.

10. The display apparatus of claim 9, wherein the pattern portion includes a bottom surface and an inclined surface connected to the bottom surface, and
the inclined surface of the pattern portion surrounds the plurality of concave portions.

11. The display apparatus of claim 9, wherein the overcoat layer includes:
a first layer including the plurality of concave portions; and
a second layer between the first layer and the pixel electrode.

12. The display apparatus of claim 11, wherein the second layer is partially overlapped with the light emission area, and
an upper surface of the second layer is flat.

13. The display apparatus of claim 11, wherein the pattern portion includes a bottom surface and an inclined surface between the bottom surface and the light extraction portion,
the second layer partially covers the inclined surface, and
an end of the second layer is in contact with the bottom surface.

14. The display apparatus of claim 7, wherein the plurality of subpixels include a first subpixel and a second subpixel for emitting light of a color different from that of the first subpixel, and
the second pattern line is disposed between the first subpixel and the second subpixel.

15. The display apparatus of claim 7, further comprising a bank covering an edge of the pixel electrode, and
the bank is disposed only in the first pattern line.

16. The display apparatus of claim 7, further comprising a bank covering an edge of the pixel electrode, and
an upper surface of the bank on the first pattern line is flat.

17. A display apparatus comprising:
a substrate including a plurality of subpixel areas; and
a light emitting element layer in the plurality of subpixel areas,
wherein each of the plurality of subpixel areas includes a light emission area and a peripheral area in the periphery of the light emission area, and
includes a reflective portion provided in the light emitting element layer in the peripheral area of each of the plurality of subpixel areas, and
the light emitting element layer is concave on a pattern portion that is concave in the peripheral area.

18. The display apparatus of claim 17, wherein the pattern portion surrounds the light emission area in the form of a slit or a trench.

19. The display apparatus of claim 17, wherein the light emitting element layer includes:
a pixel electrode in the light emission area;
a light emitting layer on the pixel electrode and the peripheral area; and
a reflective electrode on the light emitting layer, and
the reflective portion is a portion of the reflection electrode wherein the plurality of subpixels include an overcoat layer between the substrate and the pixel electrode, and
the pattern portion is formed to be concave in the overcoat layer.

20. The display apparatus of claim 19, wherein the pattern portion includes a bottom surface and an inclined surface connected to the bottom surface, and
the inclined surface forms an obtuse angle with the bottom surface.

21. The display apparatus of claim 20, wherein the overcoat layer includes:
a first layer between the substrate and the pixel electrode; and
a second layer between the first layer and the pixel electrode,
wherein the second layer partially covers the inclined surface of the pattern portion and is in contact with a portion of the bottom surface of the pattern portion.

22. The display apparatus of claim 21, further comprising a bank covering an edge of the pixel electrode,
wherein the bank is extended to cover an inclined surface of the second layer covering the inclined surface of the pattern portion and is in contact with a portion of the bottom surface of the pattern portion, wherein the plurality of subpixels include a first subpixel and a second subpixel for emitting light of a color different from that of the first subpixel, and
the bank disposed between the first subpixel and the second subpixel is disconnected from the pattern portion.

23. The display apparatus of claim 21, further comprising a bank covering an edge of the pixel electrode, wherein the bank is extended to cover an inclined surface of the second layer covering the inclined surface of the pattern portion and is in contact with a portion of the bottom surface of the pattern portion, and the light emitting layer is in contact with an inclined surface of the second layer covering the inclined surface of the pattern portion and is partially in contact with the bottom surface of the pattern portion.

24. The display apparatus of claim 17, wherein the plurality of subpixels include a light extraction portion overlapped with the light emission area, having a plurality of concave portions, and
a depth of the pattern portion is deeper than that of each of the plurality of concave portions.
